(19) United States
(12) Patent Application Publication
(10) Pub. No.: US 2006/0054090 A1
(43) Pub. Date: Mar. 16, 2006

(54) PECVD susceptor support construction

(75) Inventors: Shinichi Kurita, San Jose, CA (US); Ernst Keller, Sunnyvale, CA (US); John M. White, Hayward, CA (US)

Correspondence Address: PATTERSON & SHERIDAN, LLP, 3040 POST OAK BOULEVARD, SUITE 1500, HOUSTON, TX, 77056, US

(73) Assignee: APPLIED MATERIALS, INC.

(21) Appl. No.: 11/202,654

(22) Filed: Aug. 12, 2005

Related U.S. Application Data
(60) Provisional application No. 60/610,634, filed on Sep. 15, 2004.

(51) Int. Cl. C23C 16/00

(52) U.S. Cl. 118/728

(57) ABSTRACT

An apparatus and method for maintaining or adjusting the orientation of a large area substrate is disclosed by using multiple support plates disposed below a susceptor adapted to support the large area substrate. The multiple support plates are supported by a plurality of support shafts that are coupled to at least one actuator. The apparatus is designed to selectively adjust the horizontal cross-sectional profile of the susceptor to promote even and uniform processing. The horizontal profile may be one of planar, concave, or convex. The apparatus allows any adjustment to be made before, during, or after processing.

### CROSS REFERENCE TO RELATED APPLICATIONS:

This application claims benefit of U.S. Provisional Patent Application No. 60/610,634, filed Sep. 15, 2004 (APPM/009635L), which is incorporated herein by reference to the extent it is not inconsistent with this application.

### BACKGROUND OF THE INVENTION

1. Field of the Invention

Embodiments of the present invention generally relate to a substrate processing system in the electronics industry. More specifically, the invention relates to a system and method for supporting large area substrates in flat panel display manufacture.

2. Description of the Related Art

Flat panel displays typically employ an active matrix of electronic devices, such as insulators, conductors, and thin film transistors (TFT's) to produce flat panel screens used in a variety of devices such as television monitors and computer screens. Generally, these flat panel displays are manufactured on large area substrates which may comprise two thin plates made of glass, a polymeric material, or other suitable material capable of having an electronic device formed thereon. Layers of a liquid crystal material or a matrix of metallic contacts, a semiconductor active layer, and a dielectric layer are deposited through sequential steps and sandwiched between the two thin plates. At least one of the plates will include a conductive film that will be coupled to a power supply which will change the orientation of the crystal material and create a patterned display on the screen face.

These processes typically require the large area substrate to undergo a plurality of processing steps that deposit the active matrix material. Chemical vapor deposition (CVD) and plasma enhanced chemical vapor deposition (PECVD) are some of the well known processes for this deposition. These processes require that the large area substrate, supported in the deposition chamber by a susceptor, be maintained in a fixed position relative to the deposition apparatus during deposition to ensure uniformity in the deposited layers.

Flat panel displays and the substrates the displays are formed on have increased dramatically in size over recent years due to market acceptance of this technology. Previous generation large substrates had sizes of about 500 mm by 650 mm and have increased in size to about 1800 mm by about 2200 mm (or larger). The processes employed are time intensive and profitable production relies on high throughput resulting in usable and operable flat panel displays. Therefore, producers cannot afford to produce one inoperable unit, much less, a plurality of unusable units caused by non-uniform deposition.

The CVD and PECVD processes that are performed on these substrates generate large amounts of heat. The susceptors that are used to support the large area substrates are typically heated to heat the large area substrate and enhance the deposition process. In order to maintain a fixed position between the gas distribution plate and the susceptor during these processes, a susceptor is typically supported by a susceptor support that is resistant to heat, and expansion and contraction. The susceptor support is typically a ceramic and generally spans a length and/or width of the susceptor in monolithic strips that have suitable width and breadth to accomplish its intended purpose of maintaining a desired cross-sectional horizontal profile of the susceptor.

Susceptors have increased in size in relation to the larger substrate sizes. The susceptor support must also increase in size in relation to the susceptor so the susceptor may be suitably supported. This increase in size in the ceramic material used to support the susceptor is increasingly expensive. Therefore, there exists a need to redesign the susceptor support used for large area substrates, in order to accommodate larger substrates and keep material costs at a minimum. There is also a need in the art to manipulate a susceptor to conform to a desired shape within the deposition chamber.

FIG. 1A is a schematic side view of a chamber 2, having a lid 8, a bottom 4, and sidewalls 6. The chamber 2 also includes a substrate support or susceptor 14 which is used to support a large area substrate 16 during processing in the chamber 2, and a gas distribution plate or diffuser 10. The susceptor is supported by a susceptor support plate assembly 12, which consists of a plurality of parallel branch plates 24a-24d sandwiched below the susceptor 14, and a center plate 22. The center plate 22 is disposed on and supported by a support shaft 33, disposed on a lift plate 30, which is coupled to a vertical lifting mechanism 18 that provides vertical movement to the substrate support 14 in the direction indicated by arrow 20.

FIG. 1B is a schematic top view of the susceptor support plate assembly 12 shown in FIG. 1A. The substrate support 14 is shown by a dashed line in order to show the layout of the susceptor support plate assembly 12. The branch plates 24a-24d and the center plate 22 are large monolithic strips made of a ceramic material that are configured to support the substrate support 14.

An efficient and successful deposition process requires the substrate 16 to remain in a desired position within the chamber 2 during processing. As mentioned earlier, significant amounts of heat are produced during the PECVD process. The large area substrate 16 may reach a near molten state and, as a result, may be very pliable. The planarity of the large area substrate 16 is dependent upon the planarity and rigidity of the susceptor 14 and, in turn, the planarity of the susceptor 14 is dependent on the rigidity and planarity of the susceptor support plate assembly 12. In order for the susceptor 14 to function as a cathode in the RF excitation scheme, it is preferably made of an electrically conductive material, such as aluminum, which is vulnerable to thermal and gravitational forces that may cause a sag or bowing that will translate to the large area substrate 16. These forces are counteracted by the susceptor support plate assembly 12 by maintaining the desired cross-sectional horizontal profile of the susceptor 14 and, in turn, the cross-sectional horizontal profile of the large area substrate 16 supported thereon.

### SUMMARY OF THE INVENTION

The present invention generally provides a solution to the problems encountered by using large ceramic monoliths to support a large area susceptor by replacing the currently used support assembly with a plurality of smaller support plates positioned to maintain a desired cross-sectional horizontal profile and reduce warping of the susceptor, which translates to a conforming large area substrate.

In one embodiment, a susceptor support apparatus is described having a plurality of support plates adapted to support a susceptor in a deposition chamber, wherein at least four of the plurality of support plates are adapted to couple to at least two support shafts which extend outside the deposition chamber.

In another embodiment, an apparatus for supporting a large area substrate in a deposition chamber is described having a susceptor adapted to support the large area substrate, a plurality of susceptor support plates positioned below the susceptor, and a plurality of support shafts coupled to one or more actuators positioned below the plurality of support plates, wherein at least two of the plurality of support shafts positioned below the plurality of support plates extend outside the deposition chamber.

In another embodiment, an apparatus for adjusting the planarity of a large area substrate is described which includes a chamber having a top, a bottom, and a sidewall a susceptor disposed within the chamber adapted to support the large area substrate, and at least two support shafts that extend outside of the chamber, the at least two support shafts adapted to support the susceptor.

In another embodiment, an apparatus for supporting a large area susceptor in a deposition chamber is described having at least one support truss located outside the deposition chamber, and a plurality of support shafts coupled to the at least one support truss adapted to support the susceptor.

In another embodiment, a method of supporting a susceptor in a deposition chamber is described including supporting a center region of the susceptor with at least one support shaft, and supporting a perimeter of the susceptor with a plurality of support shafts, wherein the at least one support shaft and the plurality of support shafts extend outside the chamber and are coupled to at least one vertical actuator.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1A (Prior Art) is a schematic cross-sectional view of chamber having a susceptor support plate assembly.

FIG. 1B (Prior Art) is a schematic top view of the susceptor support plate assembly shown in FIG. 1A.

FIG. 2A is a schematic cross-sectional view of one embodiment of a plasma chamber.

FIG. 2B is a schematic top view of one embodiment of a susceptor support assembly.

FIG. 3A is a schematic cross-sectional view of another embodiment of a plasma chamber.

FIG. 3B is a schematic top view of another embodiment of a susceptor support assembly.

FIG. 4 is a schematic top view of another embodiment of a susceptor support assembly.

FIG. 5 is a schematic top view of another embodiment of a susceptor support assembly.

FIG. 6 is a schematic top view of another embodiment of a susceptor support assembly.

FIG. 7 is a schematic top view of another embodiment of a susceptor support assembly.

FIG. 8 is a schematic top view of another embodiment of a susceptor support assembly.

### DETAILED DESCRIPTION

The present invention generally provides an apparatus and method of supporting a large substrate that minimizes bowing or deflection caused by thermal and gravitational forces and provides a substantially planar surface where a susceptor or substrate support may be supported which, in turn, may support a substrate in a planar or level orientation. Some aspects also provide for isolated lifting points for counteracting substrate support deformation or end sag, or manipulating the susceptor via these lifting points to produce a desired horizontal profile in the susceptor. References made to the horizontal profile and/or the horizontal orientation of various elements depicted in the Figures refers to horizontal cross-sectional views of the particular elements as shown in the Figures.

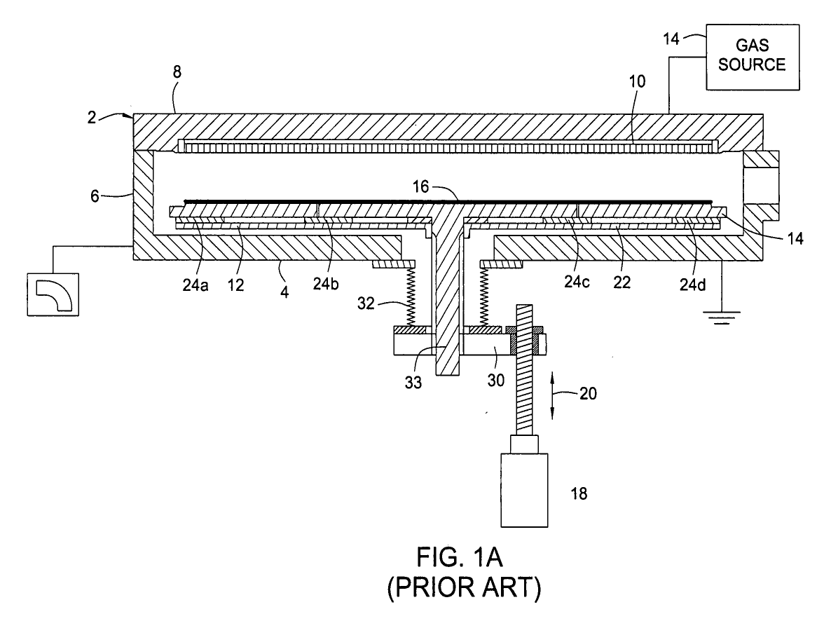

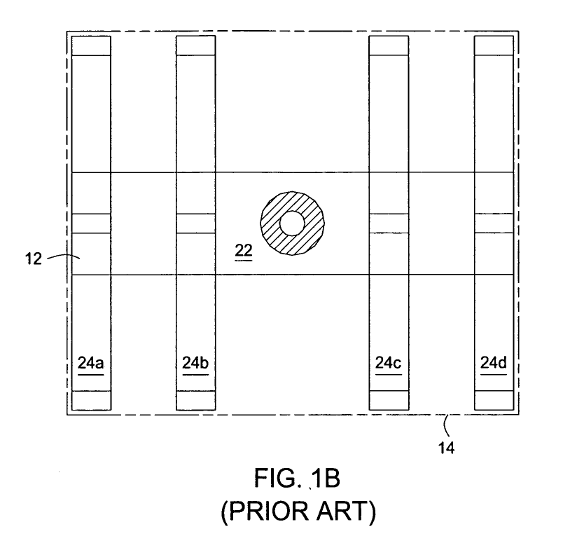

Embodiments described herein are configured to replace the susceptor support plate assembly 12 shown in FIGS. 1A, 1B by employing a susceptor support assembly having smaller ceramic support plates to support the susceptor. This is advantageous because the chambers adapted to receive the susceptor support plate assemblies do not require major redesign and the volume within the chamber that is subject to vacuum remains substantially equal to the volume of the chamber as depicted in FIG. 1A. The support plates may be less expensive to manufacture as compared to the susceptor support plate assembly 12 of FIGS. 1A and 1B. To prevent confusion, common reference numerals referring to similar elements in the drawings are duplicated, where possible.

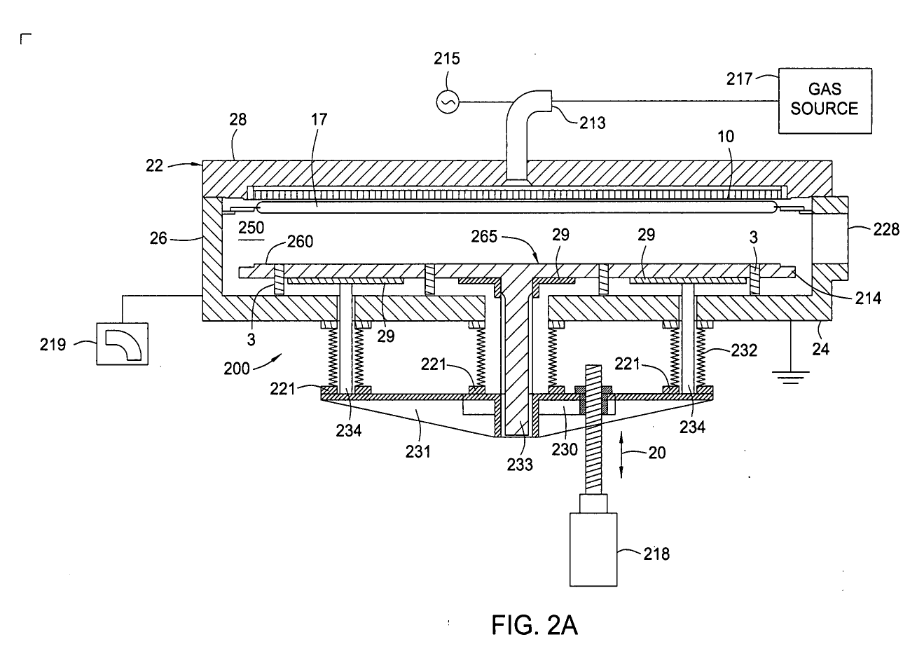

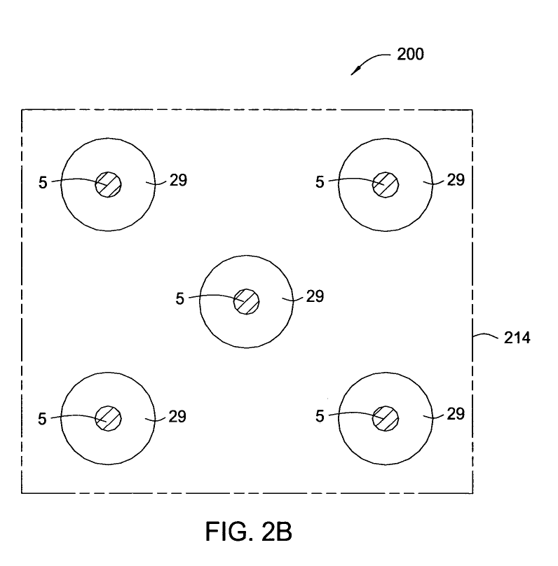

FIG. 2A is a schematic cross-sectional view of one embodiment of a plasma chamber 22 having a susceptor support assembly 200 configured to produce and maintain a desired horizontal profile in the susceptor. The desired horizontal profile may be one of planar, concave, or convex. The chamber 22 may be any size capable of accommodating any known or unknown dimensions of large area substrates. The chamber 22 includes a top 28, sidewalls 26, and a bottom 24 defining an interior region 250. The interior region 250 includes a gas distribution plate or diffuser 10 coupled to the chamber 22 above a susceptor 214. The chamber 22 is in communication with a gas source 217 that is adapted to couple to a gas inlet 213 that provides a process gas to the interior region 250. The chamber is coupled to a radio frequency power source 215 that excites the process gas into a plasma to form a plasma area 17 below the diffuser 10. The susceptor 214 may be heated by a resistive heater embedded or coupled to the susceptor 214, or the susceptor 214 may be heated by heat lamps, or some other form of thermal energy adapted to heat the susceptor. The chamber 22 is coupled to a vacuum source to evacuate the interior region 250 of the chamber. A plurality of lift pins 3 are also shown disposed in the susceptor 214 and are adapted to facilitate transfer of a large area substrate (not shown) by being movably disposed in suitable holes in the susceptor 214. In operation, the large area substrate is placed on an upper surface of the lift pins 3 by a robot (not shown). The susceptor 214 is then raised vertically to allow the lift pins 3 to retract to place the substrate on an upper surface of the susceptor 214. The susceptor 214, with the large area substrate thereon, is then raised to the plasma area 17 for processing.

The susceptor 214 is supported by a plurality of susceptor support plates 29, which are supported by a plurality of support shafts 234 and a single support shaft 233 which extend outside (i.e. ambient environment) the chamber 22 through bores in the chamber bottom 24. The size, number, and shape of the susceptor support plates 29 are configured to produce and maintain a desired horizontal profile in the susceptor 214. The desired horizontal profile may be one of planar, convex, or concave. Seals 232, such as flexible bellows, provide a vacuum tight seal isolating the chamber 22 from ambient environment in areas around the support shafts 233, 234. A susceptor support truss 231 provides support to the plurality of support shafts 234 and the support plates 29.

In one embodiment, a single vertical actuator 218 provides vertical movement which is translated to a moving block 230 which is in communication with the support truss 231 and the support truss 231 is coupled to all support shafts 233, 234. In another embodiment (not shown), the support shafts 234 may be coupled to two support trusses 231, each support truss in communication with at least one vertical actuator, while the support shaft 233 is coupled to the moving block 230 or coupled directly to the vertical actuator 218. In this embodiment, the susceptor 214 is supported adjacent a perimeter 260 of the susceptor 214 by a plurality of support shafts 234 coupled to at least two support trusses in communication with at least one vertical actuator, while the center region 265 of the susceptor 214 is supported by the support shaft 233 in direct, or indirect, communication with the vertical actuator 218. In another embodiment (not shown), the perimeter 260 of the susceptor 214 may be supported by a support truss formed in the pattern of support shafts 234 as seen from a top view, while the center region 265 of the susceptor 214 is supported by the support shaft 233 in direct, or indirect, communication with the vertical actuator 218. In this embodiment, the support truss could be formed in a rectangular pattern (as seen from a top view) having the support shafts 234 coupled thereto and adapted to contact and support the perimeter 260 of the susceptor 214. Other shapes of support trusses are contemplated, such as an X pattern, or a star pattern. Any heat from the susceptor 214 and the chamber 22 that may be absorbed by the shafts 233 and 234 may be absorbed by the moving block 230 prior to any heat being transferred to the actuator 218. Alternatively, cooling blocks 221 may be added below the seals 232, to aid in minimizing any thermal migration that may damage the actuator 218. The shafts 233 and 234 may also be manufactured to include interior cooling channels (not shown). The actuator 218 may be any actuator capable of providing vertical movement and may be powered by air, hydraulics, electrical power, or other mechanical power. When the actuator 218 is energized, the susceptor 214 is urged upward or downward in the direction of arrow 20 via the mechanical teaming of the moving block 230, the truss 231, the support shafts 233 and 234, and the support plates 29.

FIG. 2B is a schematic top view of the susceptor support assembly 200 shown in FIG. 2A. The susceptor 214 is shown in dashed lines to show the layout of the support plates 29 and corresponding susceptor lift points 5. Each of the support points 5 depict the location of the support shafts 233 and 234 below the support plates 29. Any number of susceptor support points 5 and corresponding support plates 29 may be added to the layout shown, in order to prohibit or counteract any gravitational and thermal forces that may alter the desired horizontal profile of the susceptor 214. The number of susceptor support points 5 may also be reduced by varying the size of the support plates 29. Shapes of the support plates 29 may also be varied to provide support to the susceptor 214. In one embodiment, the support plates 29 are annular and, in another embodiment, the support plates 29 are circular. In other embodiments, the support plates 29 may be polygonal shapes, such as rectangles, trapezoids, hexagons, octagons, or triangles. The susceptor support 200 may also comprise support plates 29 that may be a combination of these shapes. In another embodiment, a spacer or shim (not shown) may be placed between the support plate 29 and the shaft 233 or 234, and/or between the support plate 29 and the susceptor 214 in order to provide further adjustment and support to the susceptor 214.

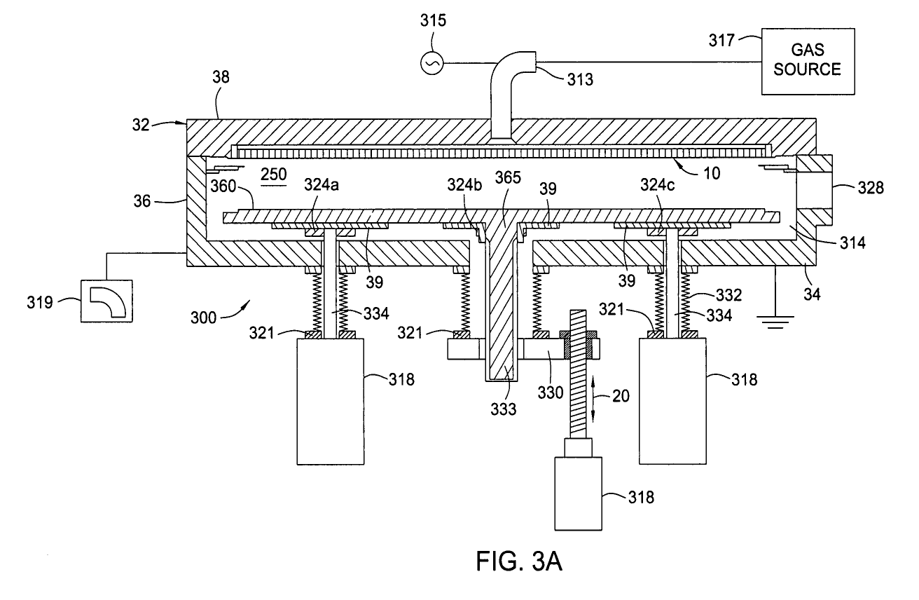

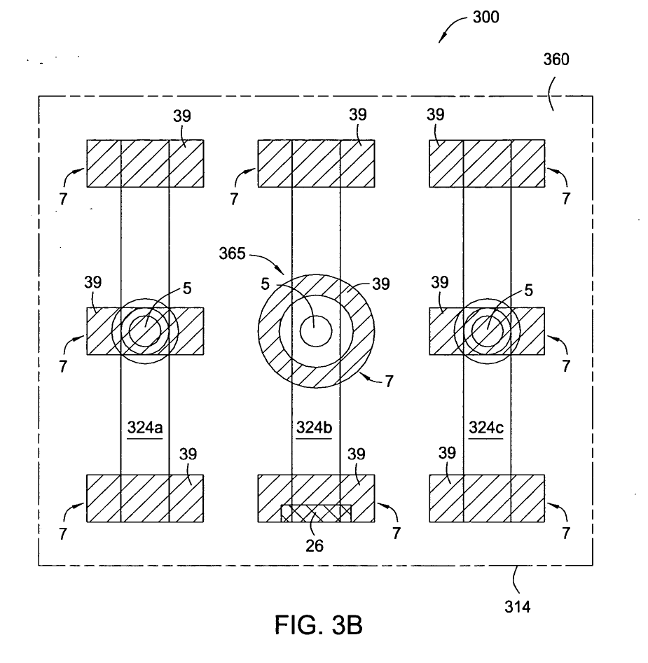

FIG. 3A is a schematic view of another embodiment of a plasma chamber 32 having a susceptor support assembly 300 configured to produce and maintain a desired horizontal profile in a susceptor 314. The desired horizontal profile may be one of planar, concave, or convex. The chamber 32 is similar to the chamber 22 shown in FIG. 2A with the exception of the susceptor support assembly 300. Also, the plasma area and support pins are not shown in for clarity. In this embodiment, the susceptor 314 is supported by susceptor support plates 39, which are supported by parallel branch plates 324a-324c. Outer parallel branch plates 324a and 324c are supported by a plurality of support shafts 334, extending outside the chamber 32, while branch plate 324b is supported by a single support shaft 333 also extending outside the chamber 32 through the chamber bottom 34. A moving block 330 is disposed below single support shaft 333 while the support shafts 334 are in direct communication with a vertical actuator 318. Alternatively, the single support shaft 333 may be in direct communication with the vertical actuator 318. The vertical actuators 318 may be any actuator capable of vertical movement and may be commonly or independently controlled. The size, number, and shape of the susceptor support plates 39 are configured to produce and maintain a desired horizontal profile in the susceptor 314. In one embodiment, the support plates 39 are annular and, in another embodiment, the support plates 39 are circular. In other embodiments, the support plates 39 may be polygonal shapes, such as rectangles, trapezoids, hexagons, octagons, or triangles. The susceptor support 300 may also comprise support plates 39 that may be a combination of these shapes. Seals 332, such as flexible bellows, provide a vacuum tight seal isolating the chamber 32 from ambient environment in areas around the support shafts 333, 334. Any heat absorbed by the shafts 333 and 334 may be absorbed by the shafts 333 and 334, and moving block 330 prior to any heat being transferred to the vertical actuators 18. Alternatively, cooling blocks 321 may be added below the seals 332, to aid in minimizing any thermal migration that may damage the actuators 318. The shafts 333 and 334 may also be manufactured to include interior cooling channels (not shown).

In this embodiment, the vertical actuators 318 may be commonly or independently controlled. A perimeter 360 of the susceptor 314 may be supported by a plurality of support plates 39 while a center area 365 of the susceptor 314 is supported by a separate plurality of support plates 39. The vertical actuators may be powered electrically, hydraulically, pneumatically, or combinations thereof. All of the vertical actuators 318 may operate similarly, or the vertical actuators 318 may be any combination of actuators, wherein, for example, some of the vertical actuators are pneumatically operated and the others are electrically operated. In operation, the vertical actuators 318 are energized either alone or in combination to provide vertical movement to the susceptor 314. These vertical actuators 18 may remain in the same position during processing or may be energized during processing to adjust the horizontal profile of the susceptor 314.

FIG. 3B is a schematic top view of the susceptor support assembly 300 shown in FIG. 3A. The susceptor 314 is shown in dashed lines to show the layout of the support plates 39 and the corresponding susceptor lift points 5. Any number, shape, or size of support plates 39 may be added to, or subtracted from, the layout shown, in order to prohibit or counteract any gravitational and thermal forces that may alter the desired horizontal profile of the susceptor 314. Lift points 5 can be seen below parallel branch plates 324a-324c and the corresponding support plates 39 overlying branch plates 324a and 324c. The lift points 5 are intended to show the placement of the support shafts 334 (under branch plates 324a and 324c) and the single support shaft 333 (under branch plate 324b). Also shown are a plurality of support points 7 that define areas of contact between the support plates 39 and the susceptor 314. The use of a shims or spacer 26 can be used with the parallel branch plates 324a-324c between the branch plates 324a-324c and the support plates 39 to further adjust the planarity of the susceptor 314.

Although three vertical actuators 318 have been used in this embodiment, any number or combination and type of vertical actuators 318 may be used. Vertical actuators 318 may be added under each susceptor support point 7 that may negate the use of parallel branch plates 324a-324c. Additional vertical actuators 318, or larger and differently shaped susceptor support plates 39 may also be employed to create additional susceptor support points 7.

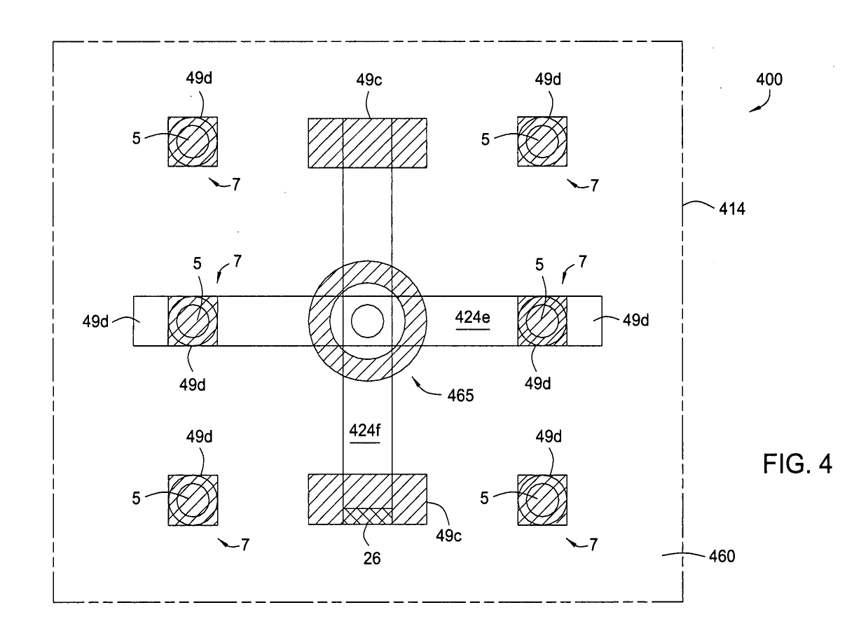

FIG. 4 is a schematic top view of the susceptor support assembly 400 configured to produce and maintain a desired horizontal profile in a susceptor 414. The desired horizontal profile may be one of planar, concave, or convex. The susceptor 414 is shown in dashed lines in order to show the layout of a plurality of support plates 49a-49d, a plurality of branch plates 424e, 424f, and lift points 5, which correspond to an upper surface of the support shafts (not shown) located below the susceptor 414. In this embodiment, a perimeter 460 and a center area 465 of the susceptor 414 is supported by a combination of the branch plates 424e, 424f, and support plates 49d. Support points 7 are also shown in the areas where the susceptor 414 and the support plates are in contact. Although the embodiment shown includes seven lift points 5, any number of lift points 5 may be added or subtracted by employing more or less vertical actuators. The support shafts may be coupled to a support truss as shown in FIG. 2A, or be in direct communication with an actuator as shown in FIG. 3A. Likewise, any number of support points 7 may be added to the layout shown by the addition of support plates and/or actuators in order to prohibit or counteract any gravitational and thermal forces that may alter the desired horizontal profile of the susceptor 414. Additional support plates may be added, for example, along the upper surface of the branch plates 424e and 424f. Any shape or combination of shapes, branch members, and vertical actuators may be used to create a desired support structure beneath the susceptor 414. Also, the use of a shim or spacer 26 can be used alone, or in combination with branch plates 424e and 424f and the support plates 49a-49d. Other spacers (not shown) may be used between the support shafts 433, 434 and the support plates 49a-49d, or between the support shafts and the branch plates 424e, 424f.

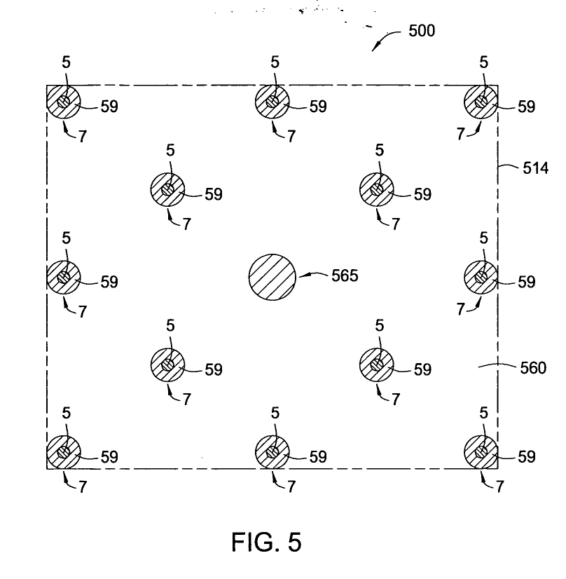

FIG. 5 is a schematic top view of a susceptor support assembly 500 configured to produce and maintain a desired horizontal profile in a susceptor 514. The desired horizontal profile may be one of planar, concave, or convex. The susceptor 514 is shown in dashed lines to show the layout of the support plates 59 and the corresponding susceptor lift points 5 each of which denote an upper surface of a support shaft (not shown). Although thirteen lift points 5 are shown in this view, any number of lift points 5 may be added or subtracted to produce and maintain the desired horizontal profile of the susceptor 514. In one embodiment, a plurality of support plates 59 are used to support the susceptor 514. In another embodiment, the susceptor 514 is in direct communication with the support shafts without the use of support plates 59. In yet another embodiment, a combination of direct support by support shafts and support plates 59 is used to support the susceptor 514. A plurality of support points 7 is also shown to define the areas of the susceptor 514 in contact with the support plates 59. Any number of support points 7 may be added or removed from the layout shown, in order to prohibit or counteract any gravitational and thermal forces that may alter the desired horizontal profile of the susceptor 514. The shapes and sizes of the support plates 59 may be also be alternated to produce and maintain the desired horizontal profile of the susceptor 514.

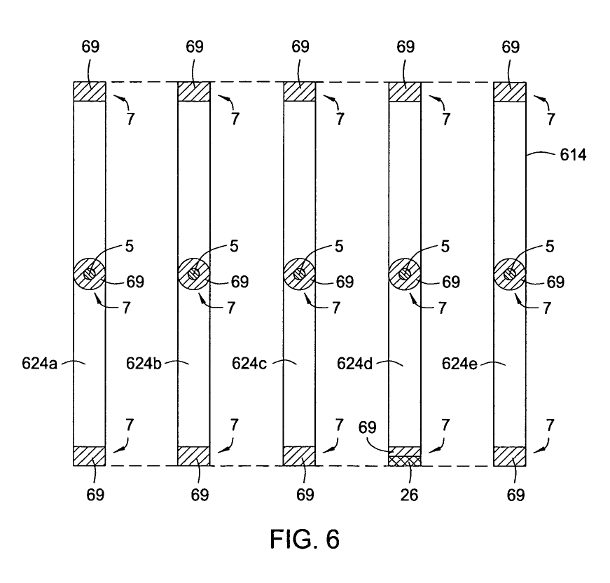

FIG. 6 is a schematic top view of a susceptor support assembly 600 configured to produce and maintain a desired horizontal profile of a susceptor 614. The desired horizontal profile may be one of planar, concave, or convex. The susceptor 614 is shown in dashed lines to show the layout of the support plates 69 and the corresponding lift points 5, which denote the location of support shafts (not shown) below a plurality of branch plates 624a-624e. In this embodiment, the five lift points 5 are supported by five support shafts coupled to at least one vertical actuator. The support shafts may be coupled to a support truss as shown in FIG. 2A, or in direct communication with a vertical actuator as shown in FIG. 3A. Although five lift points 5 are shown, any number of lift points may be added or subtracted from the layout shown. Also shown is a plurality of support points 7 defining areas of contact between the support plates 79 and the susceptor 614. Any number of support points 7 may be added to the layout shown, in order to prohibit or counteract any gravitational and thermal forces that may alter the desired horizontal profile of the susceptor 614. As in other embodiments, the support plates 69 may be of any shape, or combinations of shapes, such as circular and rectangular, and may be of any size that is configured to support the susceptor 614 in the desired horizontal profile.

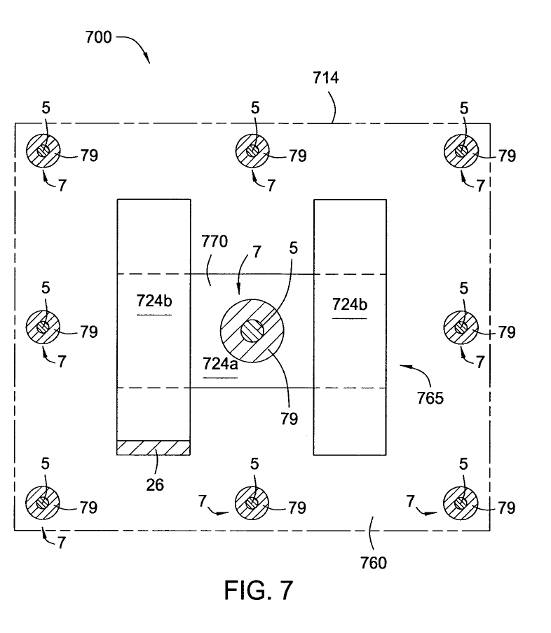

FIG. 7 is a schematic top view of a susceptor support assembly 700 configured to produce and maintain a desired horizontal profile of a susceptor 714. The desired horizontal profile may be one of planar, concave, or convex. The susceptor 714 is shown in dashed lines to show the layout of the support plates 79 and the corresponding susceptor lift points 5, which correspond to an upper surface of a plurality of support shafts (not shown) located below the susceptor 714 and a plurality of support plates 79. The support assembly 700 includes a base structure 770 which includes a longitudinal support member 724a and two transverse support members 724b coupled thereto, configured to support a center area 765 of the susceptor 714. A perimeter 760 is supported by a plurality of support shafts denoted by lift points 5 below the plurality of support plates 79. In this embodiment, the base structure 770 is coupled to a vertical actuator while the support plates 79 on the perimeter 760 are coupled to at least one vertical actuator by a support truss as described in FIG. 2A, or in direct communication with a vertical actuator as described in FIG. 3A. Any number, shape, or size of support plates 79 may be added to, or subtracted from, the layout shown, in order to prohibit or counteract any gravitational and thermal forces that may alter the desired horizontal profile of the susceptor 714. The support points 7, denoting the location of areas of contact between the susceptor 714, and the support plates 79 and the branch plates 724b, are also shown. Any corrections made to the susceptor 714 may also employ the use of a shim or spacer 26. It is also noted that in this embodiment or others, any number of support points 7 may be created under the susceptor 714, whether in direct communication with the support shafts, or in indirect communication with support shafts by the use of support plates 79.

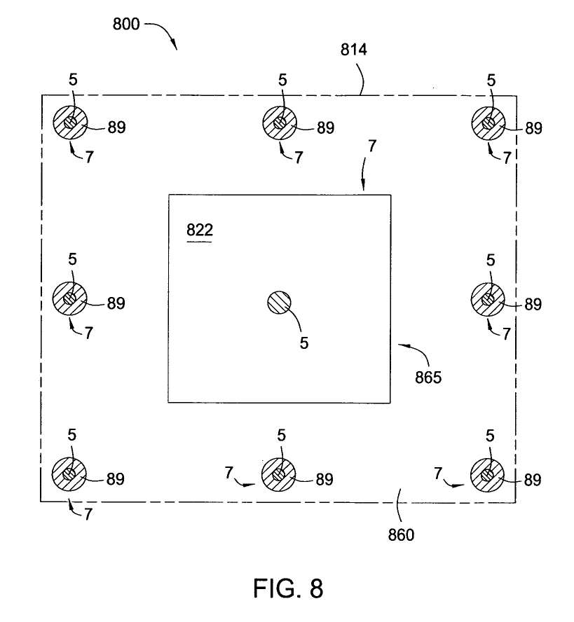

FIG. 8 is a schematic top view of a susceptor support assembly 800 configured to produce and maintain a desired horizontal profile in a susceptor 814. The desired horizontal profile may be one of planar, concave, or convex. The susceptor 814 is shown in dashed lines to show the layout of a plurality of support plates 89 and the corresponding lift points 5, which correspond to an upper surface of a plurality of support shafts (not shown) located below the susceptor 814. In this embodiment, a center plate 822 is shown supporting a center area 865 of the susceptor 814 and a plurality of support plates 89 support a perimeter 860 of the susceptor 814. The center plate 822 may be coupled to a vertical actuator while the support plates 89 on the perimeter may be coupled to a support truss as described in FIG. 2A, or coupled directly to a plurality of actuators as described in FIG. 3A. The lift points 5 around the perimeter 860 may include support plates 89 as shown, or may be in direct communication with a support shaft without the use of support plates 89. If support plates 89 are used, any number, shape, or size of support plates 89 may be added to, or subtracted from, the layout shown, in order to prohibit or counteract any gravitational and thermal forces that may alter the desired horizontal profile of the susceptor 814. The support points 7, which denote areas of contact between the susceptor 814, and support plates 89 and center plate 822, are also shown. In one embodiment, the center plate 822 is rectangular and is parallel to the edges of the susceptor 814. In another embodiment, the center plate 822 is not parallel to the perimeter of susceptor 814. For example, the center plate 822 may be rotated 45° in order to provide support for areas between the outer corners of the susceptor 814. Alternatively, the center plate 822 may take another shape such as a cross, or a star-like shape. Any number of support points 7 may be added or subtracted by adding or removing vertical actuators, or changing the size, location, and/or shape of the susceptor support points 5, or alternatively using different numbers and shapes of support plates 89. It is also noted that in this embodiment or others, any number of support points 7 may be created under the susceptor 814, whether the susceptor 814 is in direct, or indirect, communication with the support shafts.

While the foregoing has described an apparatus and method of producing and maintaining a desired horizontal profile in a susceptor, a further method of encouraging thermal expansion in the susceptor, or pre-loading the susceptor will be described. The susceptor support assemblies described above may be manufactured from a ceramic material, but in smaller sizes and varying shapes and the susceptor is typically manufactured from an aluminum material. These two materials have different coefficients of expansion and a pre-loading of the susceptor may be necessary to allow the susceptor to expand unhindered by the support plates and/or the support shafts. This is accomplished by vertically positioning the susceptor in the chamber to a position where the support pins are not in contact with the chamber.

In one embodiment, the vertical actuator that supports the center region of the susceptor is then held static and any support shafts along the perimeter of the susceptor are vertically lowered to discontinue contact between any perimeter support plates and/or support shafts by actuating at least one other vertical actuator. In another embodiment, the perimeter support shafts are held static and the center support shaft is vertically raised. In both embodiments, the susceptor may be suspended and supported at the center by a single support shaft and no other part, such as support shafts or support plates, contact the susceptor, and the lift pins disposed in the susceptor do not contact the chamber at any point. A small gap, such as between about 0.125 inches to about 1.0 inches, between the susceptor and the support plates and/or the support shafts may be created to allow the susceptor to expand radially from the center region. Heat from a heat source, such as an embedded resistive heater in the susceptor, heat lamps, or other heat source coupled to the susceptor or chamber, may be applied to promote this thermal expansion. The susceptor may be heated by this heat source to a temperature of about 100° C. to about 250° C. to facilitate this expansion.

Once the thermal expansion of the susceptor has been completed, the support shafts and/or support plates adapted to support the perimeter of the susceptor may be placed into contact with the susceptor by lowering the support shaft supporting the center region of the susceptor, or raising the support shafts adapted to support the perimeter of the susceptor. The susceptor may then be lowered by all support shafts to place a lower surface of the lift pins, which are movably disposed in the susceptor, in contact with an upper surface of the chamber bottom, thereby raising an upper surface of the support pins above the upper surface of the susceptor. A large area substrate may be introduced into the chamber through a slit valve 228 (shown in FIG. 2A) by a robot and placed above the susceptor on the upper surface of the lift pins. The robot may then be retracted and the slit valve may be closed. The chamber may be pumped down to a suitable pressure and the susceptor may be vertically raised from this transfer position by all support shafts. When the susceptor is raised, the lift pins will move away from the chamber bottom, allowing the substrate to come into contact with and lie flat on the upper surface of the susceptor. The susceptor may further be heated at this time and subsequently raised to the plasma area 17 (FIG. 2A) for processing. Once the substrate has been processed, the susceptor is lowered to the transfer position, the processed substrate is removed, and a new substrate may be introduced and processed. The susceptor, having been pre-heated by this method, may maintain its expanded orientation unless processing is halted and the susceptor is allowed to cool.

While the foregoing is directed to embodiments of the present invention, other and further embodiments of the invention may be devised without departing from the basic scope thereof, and the scope thereof is determined by the claims that follow.

1. A susceptor support apparatus, comprising;
a plurality of support plates adapted to support a susceptor in a deposition chamber, wherein at least four of the plurality of support plates are adapted to couple to at least two support shafts which extend outside the deposition chamber.

2. The apparatus of claim 1, wherein each of the plurality of support plates comprise:
a ceramic material.

3. The apparatus of claim 1, wherein the susceptor is rectangular and is adapted to support a large area substrate.

4. The apparatus of claim 2, wherein at least one of the plurality of support plates has a circular shape.

5. The apparatus of claim 2, wherein at least one of the plurality of support plates has a rectangular shape.

6. The apparatus of claim 1, wherein at least two of the at least four of the plurality of support plates are adapted to couple to the at least two support shafts with a branch plate therebetween.

7. An apparatus for supporting a large area substrate in a deposition chamber, comprising:
a susceptor adapted to support the large area substrate;
a plurality of susceptor support plates positioned below the susceptor; and
a plurality of support shafts coupled to one or more actuators positioned below the plurality of support plates, wherein at least two of the plurality of support shafts positioned below the plurality of support plates extend outside the deposition chamber.

8. The apparatus of claim 7, wherein the plurality of support shafts are coupled to one actuator, the apparatus further comprising:
a support truss coupled to the plurality of support shafts between the plurality of support plates and the actuator.

9. The apparatus of claim 7, wherein the plurality of support shafts are coupled to at least two actuators.

10. The apparatus of claim 7, wherein the plurality of support shafts are coupled to at least two actuators and the apparatus further comprises:
at least one branch plate positioned between the plurality of support plates and at least one of the plurality of support shafts.

11. The apparatus of claim 7, wherein the plurality of support plates comprise a rectangular shape, a circular shape, or combinations thereof.

12. The apparatus of claim 7, further comprising:
a center plate coupled to an actuator adapted to support a center region of the susceptor.

13. The apparatus of claim 7, wherein the susceptor is made of an aluminum material and is oriented in a planar horizontal profile when supported by the plurality of susceptor support plates.

14. An apparatus for adjusting the planarity of a large area substrate, comprising;
a chamber having a top, a bottom, and a sidewall;
a susceptor disposed within the chamber adapted to support the large area substrate; and
at least two support shafts that extend outside of the chamber, the at least two support shafts adapted to support the susceptor.

15. The apparatus of claim 14, wherein the at least two support shafts are in communication with one or more vertical actuators.

16. The apparatus of claim 14, further comprising:
a plurality of support plates coupled to the at least two support shafts.

17. The apparatus of claim 14, wherein the chamber is coupled to a vacuum source, a gas source, and a radio frequency power source.

18. The apparatus of claim 14, wherein the at least two support shafts are adapted to move in a vertical direction and the vertical movement is commonly controlled.

19. The apparatus of claim 14, wherein the at least two support shafts are adapted to move in a vertical direction and the vertical movement is individually controlled.

20. The apparatus of claim 14, wherein the susceptor is made of an aluminum material and is oriented in a planar horizontal profile when supported by the plurality of susceptor support plates.

21. An apparatus for supporting a large area susceptor in a deposition chamber, comprising:
at least one support truss located outside the deposition chamber, and
a plurality of support shafts coupled to the at least one support truss adapted to support the susceptor.

22. The apparatus of claim 21, further comprising:
at least one actuator coupled to the at least one support truss.

23. The apparatus of claim 21, further comprising:
a plurality of support plates coupled to the plurality of support shafts.

24. The apparatus of claim 21, further comprising:
a first support truss located outside the chamber coupled to a plurality of shafts adapted to support a perimeter of the susceptor; and
a second support truss located outside the chamber coupled to at least one support shaft adapted to support a center region of the susceptor.

25. A method of supporting a susceptor in a deposition chamber, comprising:
supporting a center region of the susceptor with at least one support shaft; and
supporting a perimeter of the susceptor with a plurality of support shafts, wherein the at least one support shaft and the plurality of support shafts extend outside the chamber and are coupled to at least one vertical actuator.

26. The method of claim 25, wherein a support member is coupled to the at least one support shaft and at least some of the plurality of support shafts.

27. The method of claim 25, further comprising:
providing a first vertical actuator coupled to the at least one support shaft and at least a second vertical actuator coupled to the plurality of support shafts; and
adjusting a horizontal profile of the susceptor by selective actuation of the first and the at least second vertical actuator.

28. The method of claim 27, wherein the first vertical actuator and the at least second vertical actuator are independently controlled.

29. The method of claim 27, wherein a support member is coupled to the at least one support shaft and at least some of the plurality of support shafts.

30. The method of claim 27, wherein the desired horizontal profile is planar.
